(19) United States
(12) Patent Application Publication
(10) Pub. No.: US 2026/0255908 A1
(43) Pub. Date: Aug. 27, 2026

(54) SUBSTRATE PROCESSING APPARATUS

(71) Applicant: SHIBAURA MECHATRONICS CORPORATION, Kanagawa (JP)

(72) Inventors: Kengo KAMEI, Kanagawa (JP); Jun MATSUSHITA, Kanagawa (JP); Rie TESHIMA, Kanagawa (JP); Hikaru HOSHINO, Kanagawa (JP)

(21) Appl. No.: 19/547,282

(22) Filed: Feb. 23, 2026

(30) Foreign Application Priority Data
Feb. 27, 2025 (JP) 2025-030382

(51) Int. Cl. H10P 72/00; H10P 72/76

(52) U.S. Cl. CPC H10P 72/0414; H10P 72/0436; H10P 72/7618

(57) ABSTRACT

According to one embodiment fo the present disclosure, a substrate processing apparatus includes a rotation holding unit that rotates a substrate held by a holding member, a processing liquid supply unit that supplies a processing liquid to an upper surface of the substrate while being rotated, and a heating unit that irradiates light for heating an upper surface of the substrate from above. At least a portion of the holding member in contact with the substrate transmits the light irradiated from the heating unit.

### CROSS REFERENCES TO RELATED APPLICATIONS

This application is based on and claims priority from Japanese Patent Application No. 2025-030382, filed on February 27, 2025, with the Japan Patent Office, the disclosure of which is incorporated herein in its entirety by reference.

### TECHNICAL FIELD

The present disclosure relates to a substrate processing apparatus.

### BACKGROUND

A single-wafer substrate processing apparatus is known that performs a process such as etching or resist removal by supplying a processing liquid to a substrate such as a semiconductor wafer while holding the peripheral edge of the substrate with a holding member and rotating the substrate held by the holding member using a rotary table. In such a substrate processing apparatus, heating the substrate being processed or the processing liquid on the substrate is performed to increase the temperature of the processing liquid, thereby improving the processing efficiency. See, for example, Japanese Patent Laid-Open Publication No. 2015-211201.

### SUMMARY

As an example of a heating method in a substrate processing apparatus, heating the substrate or the processing liquid on the substrate by light irradiation is known. For example, there is a substrate processing apparatus in which a light source to emit light for heating is disposed so as to face a substrate held by a rotary table. Since the substrate or a processing liquid on the substrate is heated by the light emitted from the light source, processing efficiency may be improved.

In the substrate processing apparatus using the light-based heating method, a portion of the light emitted from the light source may be directed outside the substrate and is incident on structures around the substrate. Then, the light may be reflected by the structures, and the reflected light may be incident on the substrate. For example, a rotary table serving as a structure reflects the light from the light source because its outer peripheral region is not blocked by the substrate. Accordingly, the substrate or the processing liquid on the substrate is heated not only by the light from the light source but also by the reflected light from the structures around the substrate.

However, the reflected light is blocked at a portion where a holding member for holding the peripheral edge of the substrate is provided. As a result, in the outer peripheral regions of the substrate, a region heated by the reflected light and a region not heated by the reflected light are generated. That is, since there is no heating by the reflected light in the vicinity of the holding member, the temperature becomes lower than the temperature in other portions, leading to a deterioration in the uniformity of the processing rate (e.g., the amount of processing per unit time) in the circumferential direction in the outer peripheral regions of the substrate.

Embodiments of the present disclosure have been proposed to address the above-described problems, and are intended to provide a substrate processing apparatus capable of improving temperature uniformity in the circumferential direction of a substrate.

A substrate processing apparatus according to the embodiments of the present disclosure includes: a rotation holding unit configured to rotate a substrate held by a holding member; a processing liquid supply unit that supplies a processing liquid to an upper surface of the rotating substrate; and a heating unit that irradiates light for heating from above the upper surface of the substrate, wherein at least a portion of the holding member in contact with the substrate transmits the light.

According to the embodiments of the present disclosure, it is possible to improve temperature uniformity in the circumferential direction of a substrate.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a partial cross-sectional view in an axial direction illustrating a state where a processing liquid is supplied in a substrate processing apparatus, according to a first embodiment.

FIG. 2 is a partial cross-sectional view in an axial direction illustrating a state where a rinse liquid is supplied in the substrate processing apparatus of FIG. 1.

FIG. 3 is a partial cross-sectional view in an axial direction illustrating a state where a substrate is loaded and unloaded in the substrate processing apparatus of FIG. 1.

FIGS. 4A and 4B are plan views respectively illustrating an open position and a closed position of a holding member on a rotary table.

FIG. 5 is a flowchart illustrating a processing procedure, according to an embodiment.

FIG. 6 is a graph illustrating differences in etching amounts at positions in a circumferential direction in a case where a light-non-transmissive holding member is used.

FIG. 7 is a graph illustrating differences in etching amounts at positions in a circumferential direction in a case where a light-transmissive holding member is used.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings.

### Overview

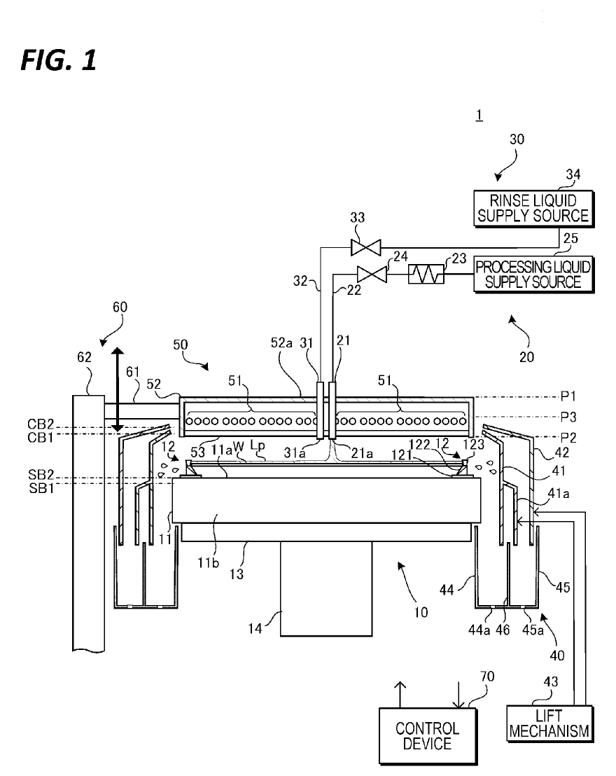

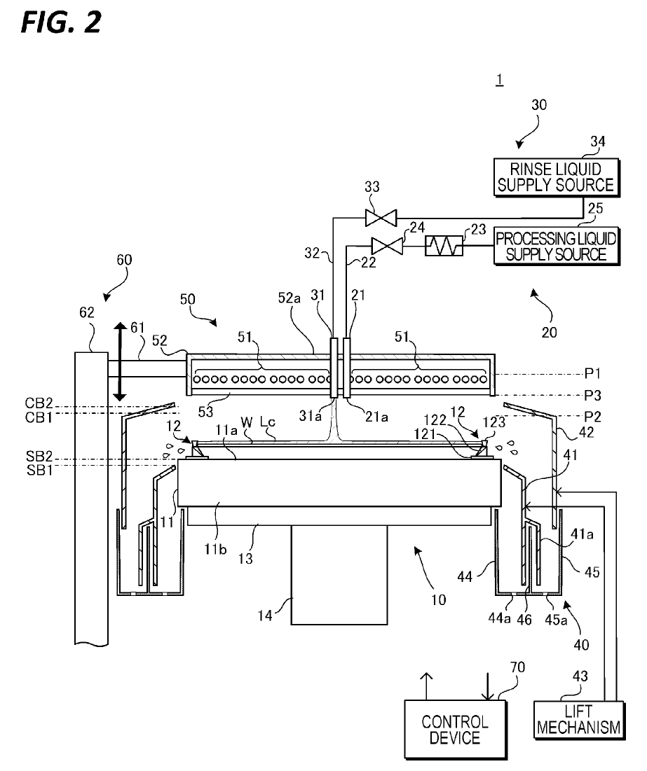

As illustrated in FIG. 1, the substrate processing apparatus 1 of the embodiment processes a substrate W by supplying a processing liquid Lp from a processing liquid supply unit 20 to the substrate W while rotating the substrate W held by a rotation holding unit 10. The substrate processing apparatus 1 is a single-wafer type apparatus that performs an etching process by supplying a processing liquid Lp having etching capability to the substrate W. As illustrated in FIG. 2, before and after the supply of the processing liquid Lp, the substrate processing apparatus 1 performs a rinse process by supplying a rinse liquid Lc from a rinse liquid supply unit 30 to the substrate W.

The substrate processing apparatus 1 includes a heating unit 50 that heats the substrate W by irradiating light. The heating unit 50 includes a light source that heats the substrate W itself by irradiating light of a wavelength for heating the substrate W. That is, the target to be heated by the heating unit 50 is the substrate W.

The substrate W to be processed is, for example, a disc-shaped silicon wafer (hereinafter, referred to as a Si substrate) having a silicon nitride film and a silicon oxide film formed on the surface thereof. The processing liquid Lp is, for example, an aqueous solution containing phosphoric acid (hereinafter referred to as a phosphoric acid solution). The concentration of phosphoric acid in the processing liquid Lp is, for example, 85 wt% to 94 wt%. The rinse liquid Lc is, for example, pure water (H₂O).

### Configuration

As illustrated in FIG. 1, the substrate processing apparatus 1 of the present embodiment includes a rotation holding unit 10, a processing liquid supply unit 20, a rinse liquid supply unit 30, a recovery unit 40, a heating unit 50, a lift mechanism 60, and a control device 70.

### Rotation Holding Unit

The rotation holding unit 10 rotates the substrate W held by a holding member 12, which will be described later. The rotation holding unit 10 includes a rotary table 11, the holding member 12, a housing unit 13, and a drive unit 14.

### Rotary Table

The rotary table 11 holds the substrate W by the holding member 12 and has a facing surface 11a that faces the held substrate W with a space therebetween. The rotary table 11 is a cylindrical member, and the upper end thereof is closed by the circular facing surface 11a. The facing surface 11a has a diameter larger than that of the substrate W. The rotary table 11 is made of, for example, polytetrafluoroethylene (PTFE).

### Holding Member

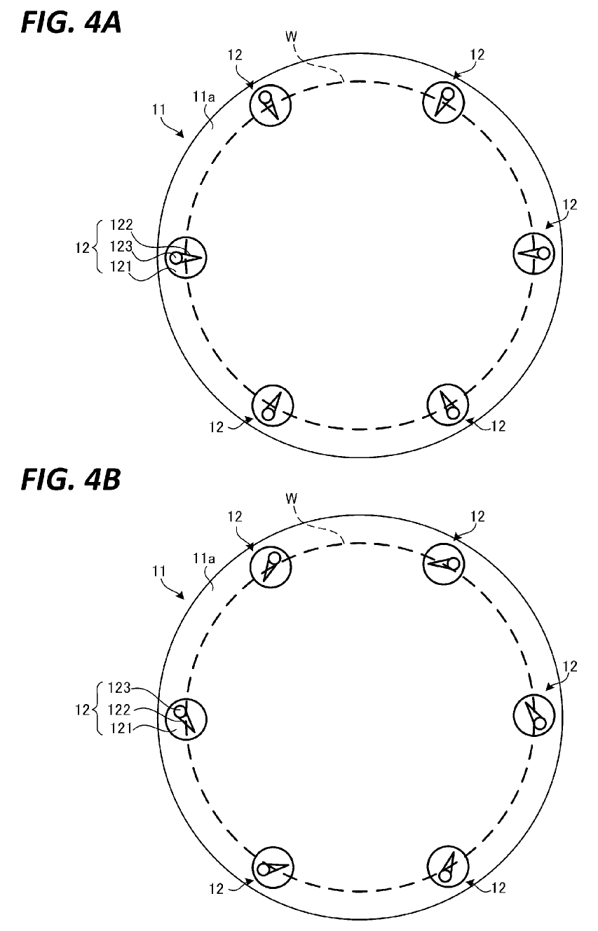

The holding member 12 is a member that holds the peripheral edge of the substrate W so as to face the facing surface 11a with a space therebetween. As illustrated in FIGS. 1, 4A, and 4B, a plurality of holding members 12 are provided at equal intervals along the positions corresponding to the peripheral edge of the substrate W while protruding on the rotary table 11. The holding members 12 are provided so as to be movable by an opening/closing mechanism (not illustrated) between a closed position where the holding members 12 contact the peripheral edge of the substrate W to hold the substrate W, and an open position where the holding members 12 move away from the peripheral edge of the substrate W to release the substrate W.

The holding members 12 transmit light from the heating unit 50, which will be described later. In the present embodiment, the entirety of each holding member 12 is formed of a light-transmitting material. For example, polychlorotrifluoroethylene (PCTFE) is used for the holding members 12. With respect to light having a wavelength of 395 nm, which is the center wavelength of light emitted by a light-emitting element 51 of the heating unit 50 described later, a polychlorotrifluoroethylene (PCTFE) measurement sample with a thickness of 3 mm exhibits a transmittance of 58.2%, a sample with a thickness of 5 mm exhibits a transmittance of 45.2%, and a sample with a thickness of 8 mm exhibits a transmittance of 30.7%. As described, the holding members 12 may be formed using a material transmissive to the light for heating the substrate W. For example, the holding members 12 may be formed using a material that exhibits a transmittance of 30% or more in a sample with a thickness of 5 mm.

The holding member 12 includes a base 121, a guide 122, and a pin 123. All of the base 121, the guide 122, and the pin 123 transmit light.

The base 121 is a cylindrical member pivotable about an axis parallel to the axis of the rotary table 11. Three or more bases 121 are arranged along a circle centered on the axis of the rotary table 11. The circle corresponds to the outer periphery of the substrate W positioned about the axis. In the present embodiment, as illustrated in FIGS. 4A and 4B, six bases 121 are arranged at equal intervals in the circumferential direction. The top surface of each base 121 is exposed from the rotary table 11. Each base 121 is provided so as to be pivotable in synchronization by an opening/closing mechanism (not illustrated).

As illustrated in FIGS. 1 to 3, the guide 122 is a plate body standing on the top surface of the base 121. The guide 122 has an inclined surface that becomes higher toward the outer periphery of the rotary table 11. The pin 123 is a cylinder provided at the top of the guide 122 at a position eccentric from the axis of the base 121. Since the diameter of the pin 123 increases upward, the outer peripheral surface thereof is an inversely tapered surface.

The pin 123 moves between the open position and the closed position according to the pivoting of the base 121. In the closed position illustrated in FIG. 4B, the pin 123 holds the substrate W by contacting the peripheral edge of the substrate W. In the open position illustrated in FIG. 4A, the pin 123 releases the substrate W by moving away from the substrate W. In the present embodiment, the six pins 123 contact the substrate W in synchronization to hold the substrate W such that the center of the substrate W coincides with the axis of the rotary table 11.

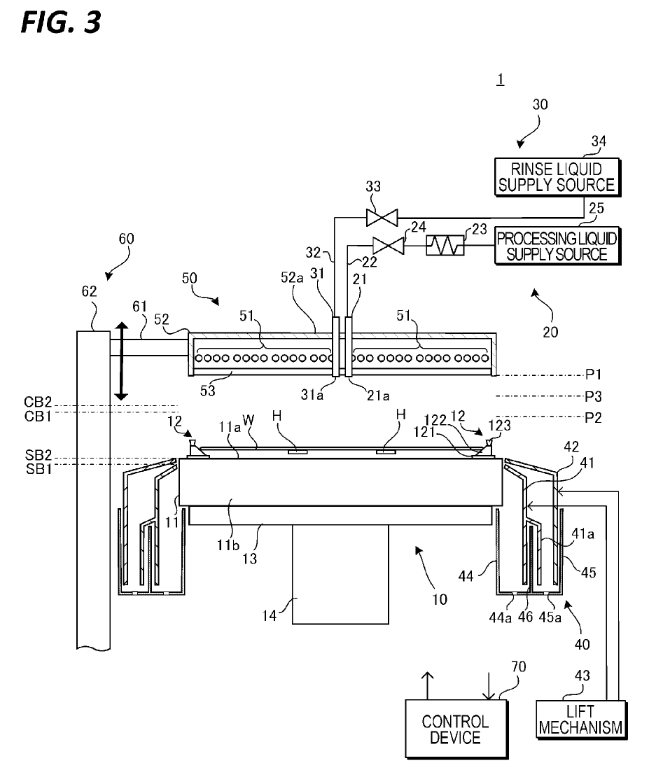

Further, in a state where the pin 123 is in the open position, the substrate W is placed on the inclined surface of the guide 122 (see, e.g., FIGS. 3 and 4A). Then, as the base 121 pivots, the substrate W is lifted by the inclined surface of the guide 122 moving therewith, and the peripheral edge of the substrate W is held by the pin 123 that has moved to the closed position (see, e.g., FIG. 4B).

### Housing Unit

The housing unit 13 houses the opening/closing mechanism of the holding members 12. The housing unit 13 is a cylindrical member. The housing unit 13 is placed in the lower part of the rotary table 11, and houses the opening/closing mechanism of the holding members 12.

### Drive Unit

The drive unit 14 is a drive source (motor) for rotating the rotary table 11. The drive unit 14 rotates the substrate W held by the pins 123 by rotating the rotary table 11.

### Processing Liquid Supply Unit

As illustrated in FIG. 1, the processing liquid supply unit 20 supplies the processing liquid Lp to a surface of the rotating substrate W opposite to the facing surface 11a. That is, the processing liquid supply unit 20 processes the substrate W by supplying the processing liquid Lp to the upper surface (surface to be processed) of the substrate W, which is held by the holding members 12 and rotated by the rotary table 11. The processing liquid supply unit 20 includes a processing liquid nozzle 21, a processing liquid supply pipe 22, a heater 23, and a valve 24.

The processing liquid nozzle 21 is inserted through a support unit 52 and a transmissive window 53 of the heating unit 50 described later, and is provided such that a dispensing opening 21a at the tip thereof faces the vicinity of the center of the substrate W held by the rotation holding unit 10.

The processing liquid nozzle 21 is connected, via the processing liquid supply pipe 22, to a processing liquid supply source 25, such as a tank, in which the processing liquid Lp is stored. In the present embodiment, the processing liquid Lp delivered from the processing liquid supply source 25 is preheated. The heater 23 is provided in the middle of the processing liquid supply pipe 22. The processing liquid Lp delivered from the processing liquid supply source 25 is heated by the heater 23, passes through the processing liquid supply pipe 22, and then dispensed from the dispensing opening 21a of the processing liquid nozzle 21 toward the vicinity of the center of the substrate W.

The temperature of the processing liquid Lp dispensed from the processing liquid nozzle 21 is, for example, 160℃. Furthermore, the valve 24 is provided in the middle of the processing liquid supply pipe 22. By opening or closing the valve 24, the dispense of the processing liquid Lp from the processing liquid nozzle 21 is started or stopped. The valve 24 is electrically connected to the control device 70, which will be described later, and its opening and closing are controlled by the control device 70.

### Rinse Liquid Supply Unit

As illustrated in FIG. 2, the rinse liquid supply unit 30 supplies a rinse liquid Lc to a surface of the rotating substrate W opposite to the facing surface 11a. That is, the rinse liquid supply unit 30 cleans the substrate W by supplying the rinse liquid Lc to the upper surface of the substrate W, which is held by the holding members 12 and rotated by the rotary table 11. Pure water, for example, may be used as the rinse liquid Lc.

The rinse liquid supply unit 30 includes a rinse liquid nozzle 31, a rinse liquid supply pipe 32, and a valve 33. The rinse liquid nozzle 31 is inserted through the support unit 52 and the transmissive window 53 of the heating unit 50, which will be described later, and is provided such that a dispensing opening 31a at the tip thereof faces the vicinity of the center of the substrate W held by the rotation holding unit 10.

The rinse liquid nozzle 31 is connected via the rinse liquid supply pipe 32 to a rinse liquid supply source 34, such as a tank, in which the rinse liquid Lc is stored. The rinse liquid Lc delivered from the rinse liquid supply source 34 passes through the rinse liquid supply pipe 32 and is dispensed from the dispensing opening 31a of the rinse liquid nozzle 31 toward the vicinity of the center of the substrate W. The valve 33 is provided in the middle of the rinse liquid supply pipe 32. By opening or closing the valve 33, the dispense of the rinse liquid Lc from the rinse liquid nozzle 31 is started or stopped. The valve 33 is electrically connected to the control device 70, which will be described later, and its opening and closing are controlled by the control device 70.

### Liquid Receiver Unit

As illustrated in FIG. 1, the recovery unit 40 is provided so as to surround the rotation holding unit 10 and receives the processing liquid Lp and the rinse liquid Lc splashed from the rotating substrate W. The recovery unit 40 discharges the received processing liquid Lp and rinse liquid Lc to the outside of the substrate processing apparatus 1.

The recovery unit 40 includes a first cup 41, a second cup 42, a lift mechanism 43, a first liquid receiver 44, and a second liquid receiver 45. The first cup 41 and the second cup 42 cover the outer periphery of the rotating substrate W with a space therebetween from the substrate W and the rotary table 11. Each of the first cup 41 and the second cup 42 is a cylindrical body bent such that the diameter of its upper portion narrows. The first cup 41 has a smaller diameter than the second cup 42 and is disposed inside the second cup 42.

The first cup 41 is provided with a skirt portion 41a on a side surface facing the second cup 42. The skirt portion 41a is a cylindrical body that is bent such that the diameter of its upper portion narrows, and the upper end thereof is fixed to the side surface of the first cup 41. By the skirt portion 41a, an annular space that is closed at the top and open at the bottom is formed in the lower part of the first cup 41.

The first cup 41 is provided so as to be movable between a standby position SB1 and a cover position CB1. The standby position SB1 is a lowered position that allows the substrate W to be loaded and unloaded (see, e.g., FIG. 3). The standby position SB1 is at a height equal to or lower than the height of the facing surface 11a of the rotary table 11. The cover position CB1 is a position where the first cup 41 is raised to receive the processing liquid Lp splashed from the substrate W (see, e.g., FIG. 1). Since the heating unit 50 irradiates light while the substrate W is being processed with the processing liquid Lp, the first cup 41 is at the cover position CB1 when light is being irradiated by the heating unit 50. At the cover position CB1, the height of the upper end of the inner wall of the first cup 41 is at least as high as the position where the heating unit 50 emits light. That is, the height of the upper end of the inner wall of the first cup 41 is at the same height as or higher than the bottom surface of the transmissive window 53 of the heating unit 50.

The second cup 42 is provided so as to be movable between a standby position SB2 and a cover position CB2. The standby position SB2 is a lowered position that allows the substrate W to be loaded and unloaded (see, e.g., FIG. 3). The cover position CB2 is a position where the second cup 42 is raised to receive the rinse liquid Lc splashed from the substrate W (see, e.g., FIG. 2), or a position where it is raised when the first cup 41 is at the cover position CB1 (see, e.g., FIG. 1).

The lift mechanism 43 is a mechanism that moves the first cup 41 and the second cup 42 individually in an up and down direction. As for the lift mechanism 43, for example, various mechanisms for moving the first cup 41 and the second cup 42 in a direction parallel to the axis of the rotary table 11, such as a cylinder or a ball screw mechanism, may be applied, but details thereof are omitted. The lift mechanism 43 may be configured separately for the first cup 41 and the second cup 42.

The first cup 41 moves to the cover position CB1 when a process using the processing liquid Lp is performed, and moves to the standby position SB1 when a rinse process using the rinse liquid Lc is performed or when the substrate W is loaded or unloaded. The second cup 42 moves to the cover position CB2 when a rinse process using the rinse liquid Lc is performed or when a process using the processing liquid Lp is performed, and moves to the standby position SB2 when the substrate W is loaded or unloaded.

The first liquid receiver 44 is an annular container provided below the first cup 41 and having an open top. The second liquid receiver 45 is an annular container provided below the second cup 42 and having an open top. The first liquid receiver 44 and the second liquid receiver 45 are configured by partitioning the inside of an annular container into an inner portion and an outer portion by a cylindrical partition wall 46. The first liquid receiver 44 receives the processing liquid Lp that has fallen downward from the first cup 41. The second liquid receiver 45 receives the rinse liquid Lc that has fallen downward from the second cup 42.

Since the partition wall 46 is interposed between the side wall of the first cup 41 and the inner wall of the skirt portion 41a without contact, a labyrinth structure, which is a bent path, is formed, making it difficult for the processing liquid Lp to enter the second liquid receiver 45. Drainage ports 44a and 45a are formed at the bottoms of the first liquid receiver 44 and the second liquid receiver 45, respectively. The drainage port 44a is connected to a recovery path for the processing liquid Lp via a drainage pipe (not illustrated) for discharging the processing liquid Lp. The drainage port 45a is connected to a recovery path for the rinse liquid Lc via a drainage pipe (not illustrated) for discharging the rinse liquid Lc.

### Heating Unit

As illustrated in FIG. 1, the heating unit 50 irradiates light for heating from above the surface of the substrate W to which the processing liquid Lp is supplied. That is, the heating unit 50 heats the substrate W by irradiating light from a light source onto the substrate W held and rotated by the rotation holding unit 10.

The processing liquid Lp supplied to the vicinity of the center of the substrate W flows so as to spread toward the peripheral edge of the substrate W by centrifugal force. At this time, when there is no further heating, the supplied high-temperature (160 ℃) processing liquid Lp decreases in temperature as it flows across the substrate W, due to the heat conduction to the substrate W or heat dissipation. Therefore, by heating the substrate W, the processing liquid Lp on the substrate W may be heated by heat conduction from the substrate W, and the processing liquid Lp on the substrate W may be maintained at a relatively high temperature. The output of the heating unit 50 may be controlled not only to maintain the temperature of the processing liquid Lp but also to further increase the temperature on the substrate W.

A light-emitting element 51 is used as the light source. The light-emitting element 51 emits light (e.g., electromagnetic waves) of a wavelength that heats the substrate W by being absorbed by the substrate W. Further, the light emitted by the light-emitting element 51 is light of a wavelength that transmits through the processing liquid Lp. Here, “absorbed by the substrate W” means that the light incident on the substrate W is absorbed to an extent sufficient to heat the substrate W, and includes not only complete absorption by the substrate W but also a case where a part of the light is reflected by or transmitted through the substrate W. Also, "transmits through the processing liquid Lp" means that the light incident on the processing liquid Lp transmits through the processing liquid Lp to an extent sufficient to heat the substrate W, and includes a case where a part of the light is absorbed by or reflected by the processing liquid Lp.

As for the light-emitting element 51, for example, an LED that emits light for heating may be used. The wavelength of the light emitted by the LED is, for example, in the range of 350 nm to 1,060 nm. The center wavelength may be in the range of 395 nm to 940 nm. In the present embodiment, an LED having a center wavelength of 395 nm for the emitted light is used. The output of the light-emitting element 51 is controlled by the control device 70, which will be described later.

Accordingly, even when the light from the light-emitting element 51 is irradiated from above the space where the substrate W is held, that is, from above the processing liquid Lp supplied to the substrate W, the light transmits through the processing liquid Lp on the substrate W and is absorbed by the substrate W, thereby heating the substrate W. Then, the temperature of the processing liquid Lp increases due to the heat conduction from the substrate W, so that the etching rate (processing rate) increases.

As described above, in the present embodiment, the entirety of each holding member 12 transmits light. For this reason, when the light from the heating unit 50 is reflected by the structures not shielded by the substrate W, the reflected light is incident on the substrate W and, even at the portions held by the holding members 12, the reflected light transmits through the holding members 12 and is incident on the substrate W. Accordingly, the entire circumference of the substrate W is heated by the reflected light.

The heating unit 50 includes the support unit 52 and the transmissive window 53 in addition to the light-emitting element 51 described above. The support unit 52 is a member that supports a plurality of light-emitting elements 51. The support unit 52 is a cylindrical member whose upper end is closed by a top plate 52a. The diameter of the support unit 52 is the same as or larger than the diameter of the substrate W. The support unit 52 is disposed above the rotary table 11 at a position facing the facing surface 11a with a space therebetween. Accordingly, the heating unit 50 is provided so as to irradiate the light from the light-emitting element 51 from above the space where the substrate W is held by the rotation holding unit 10.

The transmissive window 53 is a disk-shaped member that covers the end of the support unit 52 facing the rotary table 11. The transmissive window 53 is formed of a material that is resistant to the processing liquid Lp and through which the light emitted from the light-emitting element 51 transmits. For example, the transmissive window 53 made of quartz glass or the like is used.

The transmissive window 53 has a size equal to or larger than the substrate W. That is, the transmissive window 53 has the same diameter as or a larger diameter than the substrate W. Further, by making the diameter of the transmissive window 53 of the present embodiment smaller than the facing surface 11a of the rotary table 11, irradiation of light onto structures outside the substrate W is suppressed. The light from the light-emitting element 51 is irradiated onto the substrate W through the transmissive window 53. As described above, when light is being irradiated by the heating unit 50, the height of the upper end of the inner wall of the first cup 41 is at least as high as the position where the heating unit 50 emits light. That is, the height of the upper end of the inner wall of the first cup 41 at the cover position CB1 is above the height of the bottom surface of the transmissive window 53.

As illustrated in FIG. 1, two through-holes are provided near the center of the top plate 52a of the support unit 52, and through-holes are provided in the transmissive window 53 at positions facing the through-holes of the top plate 52a, respectively. The processing liquid nozzle 21 and the rinse liquid nozzle 31 are inserted into the two sets of corresponding through-holes of the top plate 52a and the transmissive window 53, respectively, and the dispensing openings 21a and 31a at the respective tips are exposed from the transmissive window 53 and directed toward the substrate W.

The plurality of light-emitting elements 51 are attached to the support unit 52 so as to face the rotary table 11 with the transmissive window 53 interposed therebetween. The heating unit 50 has a plurality of regions in which the light-emitting elements 51 are arranged. That is, the plurality of light-emitting elements 51 are arranged separately in a plurality of regions. In the present embodiment, the light-emitting elements 51 are provided in regions corresponding to different positions in the radial direction of the substrate W, and the output of the light-emitting elements 51 is controllable for each region. Further, the plurality of light-emitting elements 51 are arranged so as to be able to irradiate light over the entire surface to be processed of the substrate W.

### Lift Mechanism

As illustrated in FIG. 1, the lift mechanism 60 supports the heating unit 50 and moves the heating unit 50 up and down. The lift mechanism 60 includes an arm 61 and a column 62. The arm 61 is a member extending in a direction parallel to the substrate W, and one end of the arm 61 is connected to an outer peripheral portion of the support unit 52. The column 62 is erected in a direction orthogonal to the substrate W and supports the other end of the arm 61. The column 62 is provided so as to be movable up and down by a drive source (not illustrated) such as a ball screw mechanism or a cylinder.

The heating unit 50 is positioned at any one of the following heights by the drive of the lift mechanism 60: a loading/unloading position P1, a heating position P2, and a rinse position P3. Each position is as follows:

Loading/unloading position P1: A height position separated upward from the rotary table 11 so that a hand H of a transfer robot may be inserted (see, e.g., FIG. 3).

Heating position P2: A height position closer to the substrate W than the loading/unloading position P1 (see, e.g., FIG. 1). However, the heating unit 50 does not contact the processing liquid Lp on the substrate W.

Rinse position P3: A height position between the loading/unloading position P1 and the heating position P2 (see, e.g., FIG. 2).

### Control Device

The control device 70 controls each component of the substrate processing apparatus 1. In order to implement various functions of the substrate processing apparatus 1, the control device 70 includes a processor that executes a program, a memory that stores programs and various kinds of information such as operating conditions, and a control circuit that controls each component. That is, the control device 70 controls the rotation holding unit 10, the processing liquid supply unit 20, the rinse liquid supply unit 30, the recovery unit 40, the heating unit 50, the lift mechanism 60, and the like.

Specifically, the control device 70 controls the operations of the opening/closing mechanism and the drive unit 14 of the rotation holding unit 10, the heater 23 and the valve 24 of the processing liquid supply unit 20, the valve 33 of the rinse liquid supply unit 30, the lift mechanism 43 of the recovery unit 40, the lift mechanism 60, and the like.

### Operation

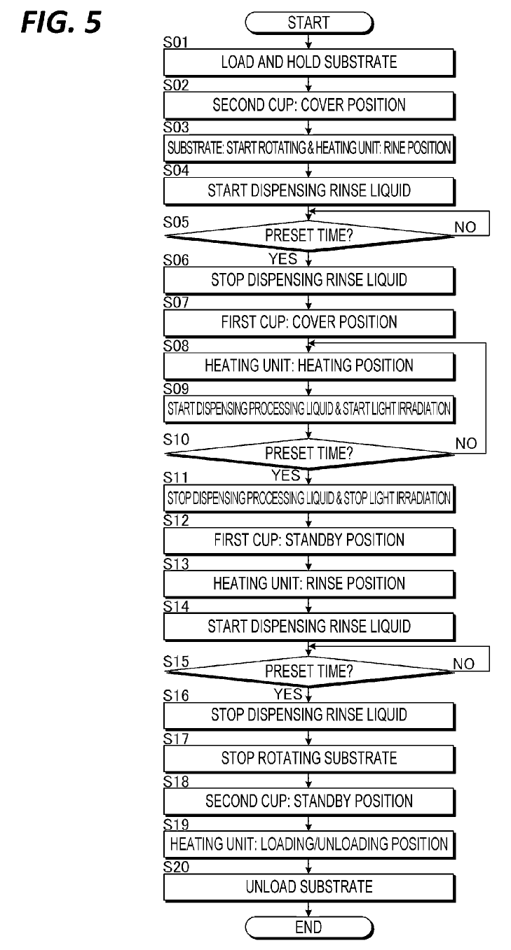

The operation of the substrate processing apparatus 1 of the present embodiment as described above will be described with reference to the flowchart of FIG. 5 in addition to the above-mentioned FIGS. 1 to 4. A substrate processing method for processing the substrate W according to the following procedure is also an aspect of the present embodiment.

As illustrated in FIG. 3, the heating unit 50 is positioned at the loading/unloading position P1 in advance, the first cup 41 is positioned at the standby position SB1, and the second cup 42 is positioned at the standby position SB2. The valve 24 of the processing liquid supply unit 20 and the valve 33 of the rinse liquid supply unit 30 are closed.

In this state, the pins 123 are set to the open position, and after the substrate W held by the hand H of the transfer robot is loaded between the heating unit 50 and the rotary table 11, the pins 123 are set to the closed position, so that the peripheral edge of the substrate W is supported by the pins 123 (see, e.g., FIG. 4B). Accordingly, the substrate W is held on the facing surface 11a of the rotary table 11 with a space therebetween (Step S01). At this time, the substrate W is positioned such that the center of the substrate W coincides with the rotation axis of the rotary table 11. Thereafter, as illustrated in FIG. 2, the second cup 42 is raised and positioned at the cover position CB2 (Step S02).

Next, as the rotary table 11 rotates, the substrate W held by the pins 123 starts rotating, and the heating unit 50 is lowered and positioned at the rinse position P3 (Step S03).

Then, the valve 33 of the rinse liquid supply unit 30 is opened, and the rinse liquid Lc is dispensed from the rinse liquid nozzle 31 toward the vicinity of the center of the substrate W (Step S04). When the rinse liquid Lc is supplied to the rotating substrate W, the rinse liquid Lc sequentially moves toward the outer periphery of the substrate W and spreads across the entire surface to be processed of the substrate W. The rinse liquid Lc splashed outward from the substrate W strikes the inner wall of the second cup 42, falls downward, and flows into the second liquid receiver 45. Then, the rinse liquid Lc is discharged from the drainage port 45a formed in the second liquid receiver 45.

Without such supply of the rinse liquid Lc, when the processing liquid Lp is supplied, the processing liquid Lp may not spread and wet the entire surface to be processed of the substrate W due to surface tension, resulting in a processing non-uniformity. In the present embodiment, in order to prevent such processing non-uniformity, the rinse liquid Lc is supplied before the processing liquid Lp is supplied. When a preset rinse time has elapsed (YES in Step S05), the valve 33 of the rinse liquid supply unit 30 is closed, and the dispense of the rinse liquid Lc from the rinse liquid nozzle 31 is stopped (Step S06).

Subsequently, as illustrated in FIG. 1, the first cup 41 is raised and positioned at the cover position CB1 (Step S07), and the heating unit 50 starts to descend, reaching the heating position P2 and stopping there (Step S08). Then, the valve 24 of the processing liquid supply unit 20 is opened, and the processing liquid Lp is dispensed from the processing liquid nozzle 21 toward the vicinity of the center of the substrate W. At the same time, heating of the substrate W by light irradiation from the light-emitting elements 51 is started (Step S09).

When the processing liquid Lp is supplied to the rotating substrate W, the processing liquid Lp sequentially moves toward the outer periphery of the substrate W and spreads across the entire surface to be processed, so that the process using the processing liquid Lp proceeds. The processing liquid Lp splashed outward from the substrate W strikes the inner wall of the first cup 41, falls downward, and flows into the first liquid receiver 44. Then, the processing liquid Lp is discharged from the drainage port 44a formed in the first liquid receiver 44.

Since the rinse liquid Lc has been supplied to the surface of the substrate W to be processed in advance, the processing liquid Lp wets and spreads over the entire surface of the substrate W, thereby preventing processing non-uniformity. Furthermore, since the substrate W is heated by the light from the heating unit 50, a temperature decrease of the processing liquid Lp on the substrate W is suppressed. Reflected light from the facing surface 11a and side surface 11b of the rotary table 11 and from the first cup 41 is incident directly on the substrate W at locations where the holding members 12 are not present, and transmits through the holding members 12 and is incident on the substrate W at locations where the holding members 12 are present. For this reason, variations in the amount of incident light in the circumferential direction are reduced. The process using the processing liquid Lp is continued until a preset processing time has elapsed (NO in Step S10).

When the preset processing time has elapsed (YES in Step S10), the valve 24 of the processing liquid supply unit 20 is closed to stop the supply of the processing liquid Lp from the processing liquid nozzle 21, and the irradiation of light from the light-emitting elements 51 is stopped (Step S11).

As illustrated in FIG. 2, the first cup 41 is positioned at the standby position SB1 (Step S12), and the heating unit 50 starts to rise, reaching the rinse position P3 and stopping there (Step S13). Then, the valve 33 of the rinse liquid supply unit 30 is opened, and the rinse liquid Lc is dispensed from the rinse liquid nozzle 31 toward the vicinity of the center of the substrate W (Step S14). When the rinse liquid Lc is supplied to the rotating substrate W, the rinse liquid Lc sequentially moves toward the outer periphery and spreads across the entire surface to be processed.

When the rinse liquid Lc is supplied to the processing liquid Lp, which is a phosphoric acid solution, a large amount of water vapor is generated. At this time, since the heating unit 50 is at the rinse position P3, which is a position further separated from the substrate W than the heating position P2, it is possible to suppress the adhesion of water vapor to the heating unit 50. In addition, since the rinse position P3 is a position closer to the substrate W than the loading/unloading position P1, liquid splashing may be suppressed, and the adhesion of liquid droplets to the heating unit 50 may be suppressed.

When a preset rinse time has elapsed (YES in Step S15), the valve 33 of the rinse liquid supply unit 30 is closed, and the dispense of the rinse liquid Lc from the rinse liquid nozzle 31 is stopped (Step S16). As the rotary table 11 stops, the rotation of the substrate W held by the pins 123 is stopped (Step S17). Thereafter, the second cup 42 is lowered and positioned at the standby position SB2 (Step S18).

As illustrated in FIG. 3, the heating unit 50 is raised and positioned at the loading/unloading position P1 (Step S19). In this state, the hand H of the transfer robot is inserted below the substrate W, and the pins 123 are set to the open position, so that the substrate W is placed on the hand H and unloaded to the outside (Step S20). At this time, the rinse liquid Lc is in a state of being held on the substrate W.

### Advantageous Effects

(1) The substrate processing apparatus 1 of the present embodiment includes the rotation holding unit 10 that rotates the substrate W held by the holding member 12, the processing liquid supply unit 20 that supplies the processing liquid Lp to the upper surface of the rotating substrate W, and the heating unit 50 that irradiates light for heating on to the upper surface of the substrate W from above, in which at least a portion of the holding member 12 in contact with the substrate W transmits the light.

When the light emitted from the heating unit 50 is reflected by the structures around the substrate W, such as the rotary table 11 and the first cup 41, a portion of the reflected light is directed toward the substrate W. At locations where the holding members 12 are not present, the reflected light is not blocked by the holding members 12 and is incident on the substrate W, thereby heating the substrate W. Furthermore, in the present embodiment, even at locations where the holding members 12 are present, the holding members 12 transmit the reflected light, so that the reflected light is incident on the substrate W and heats the substrate W. Accordingly, the difference in the amount of incident light in the circumferential direction of the substrate W is reduced, and the uniformity of the temperature in the circumferential direction is improved.

(2) The light-transmitting portion of the holding member 12 is made of PCTFE. This provides the light transmissivity required to heat the substrate W while ensuring resistance to the processing liquid Lp.

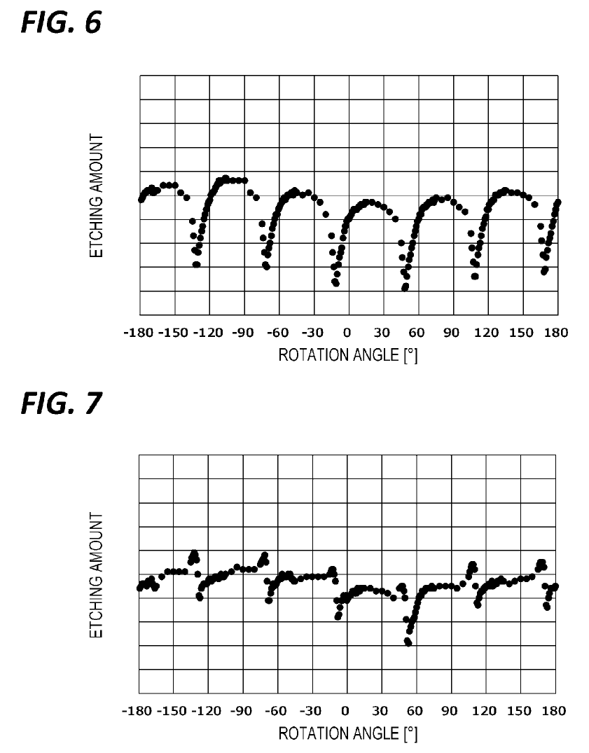

FIGS. 6 and 7 are graphs illustrating examples in which the etching amount in the outer peripheral region of the substrate W was measured for one full revolution (360°). FIG. 6 illustrates a case where the holding members 12 are formed of black PTFE (transmittance of approximately 0%), and FIG. 7 illustrates a case where the holding members 12 are formed of light-transmitting PCTFE. In FIGS. 6 and 7, the horizontal axis represents the position in the circumferential direction (e.g., rotation angle), and the vertical axis represents the etching amount. Since the scales of the vertical and horizontal axes in FIGS. 6 and 7 are the same, the magnitude of the difference in the etching amounts may be compared. In FIGS. 6 and 7, a decrease in the etching amount is observed at a cycle of 60°. The positions where the etching amount decreases correspond to the locations where the six holding members 12 are provided. As can be seen from FIGS. 6 and 7, in the case of the holding members 12 formed of light-transmitting polychlorotrifluoroethylene (PCTFE), the difference between the locations where the etching amount is large and the locations where it is small in the circumferential direction is smaller than in the case where the holding members 12 are formed of black polytetrafluoroethylene (PTFE).

(3) The entirety of each holding member 12 transmits light. For this reason, the amount of reflected light that is transmitted increases, further reducing the difference in the amount of light in the circumferential direction compared to locations where the holding members 12 are not present. In addition, manufacturing and processing of the holding members 12 are facilitated because the entirety may be formed of a common material.

(4) The heating unit 50 includes the transmissive window 53 having a size equal to or larger than the substrate W, and irradiates light onto the substrate W through the transmissive window 53. For this reason, the entire surface of the substrate W may be heated by light irradiation, and blocking of the reflected light from structures around the substrate W may be suppressed.

(5) The heating unit 50 includes a plurality of LEDs as the light-emitting elements 51. For this reason, the entire substrate W may be uniformly heated by the plurality of LEDs.

### Modifications

(1) The holding members 12 do not need to be entirely light-transmissive. It is sufficient that at least a portion in contact with the substrate W transmits light. For example, in the case of the holding members 12 having the above-described structure, only the pins 123, or only the pins 123 and the guides 122, may be configured to transmit light. Alternatively, only the portions exposed upward from the rotary table 11 may be configured to transmit light.
(2) The light source of the heating unit 50 is not limited to an LED. Any light source capable of heating a target to be heated by light, may be used. For example, a halogen lamp or a flash lamp may be used as the light source. According to an embodiment, arranging a plurality of LEDs allows for more uniform heating.
(3) The light-transmitting material is not limited to PCTFE. For example, quartz glass may be used as the light-transmitting material.
(4) The holding members 12 are only required to be capable of holding the peripheral edge of the substrate W, and are not limited to the configuration using the eccentrically rotating pins 123. For example, hook-shaped members that pivot about a horizontal axis in a direction to contact or move away from the peripheral edge of the substrate W may be used.
(5) The process performed by the substrate processing apparatus 1 is not limited to an etching process. Any apparatus that processes the substrate W by supplying the processing liquid Lp while heating the substrate W may be used. For example, a resist removal process for removing a resist film formed on the substrate W may be performed.
(6) The processing liquid Lp is not limited to a phosphoric acid solution. Any processing liquid Lp that requires heating may be used. For example, hydrofluoric acid or the like may also be used. In the case of a resist removal process, sulfuric acid-hydrogen peroxide mixture (SPM) or the like may also be used as the processing liquid Lp.
(7) The substrate W to be processed may be a Si substrate having a resist formed on the surface thereof. Furthermore, the substrate W is not limited to the Si substrate. For example, a SiC substrate (silicon carbide wafer) may be used.
(8) The number and arrangement positions of the light-emitting elements 51 are not limited to the aspects exemplified above. Light from a light source may be guided onto and emitted toward the substrate W via an optical fiber. Therefore, the light-emitting elements 51 do not necessarily need to be disposed above the substrate W.
(9) In the above aspect, the rinse liquid nozzle 31 is configured to pass through the support unit 52 and the transmissive window 53. However, a mechanism for moving the rinse liquid nozzle 31 in a horizontal direction may be provided so that the rinse liquid nozzle 31 is moved above the vicinity of the center of the substrate W when supplying the rinse liquid Lc.
(10) The support unit 52 in which the light-emitting elements 51 are arranged is a circular member having a diameter equal to or larger than the diameter of the substrate W, but not limited thereto. Any configuration may be used as long as the light is capable of being irradiated onto the entire surface of the rotating substrate W. For example, the support unit 52 may be a rectangular member having a size capable of covering the radius of the substrate W. When light is irradiated over the radius of the substrate W, the entire surface of the substrate W may be irradiated as the substrate W rotates. Further, the support unit 52 may be provided so as to be swingable in a horizontal direction, and the entire surface of the substrate W may be irradiated by swinging while emitting light from the light-emitting elements 51.

In this way, when the support unit 52 is smaller than the diameter of the substrate W, a mechanism for moving the processing liquid nozzle 21 in the horizontal direction may be provided so that the nozzle is moved above the substrate W during the supply of the processing liquid. That is, the processing liquid nozzle 21 may be disposed anywhere as long as the processing liquid Lp is capable of being supplied toward the vicinity of the center of the substrate W while performing light irradiation from the light-emitting elements 51.

### Other Embodiments

The embodiments of the present disclosure and modifications of each component have been described above, but these embodiments and modifications are presented as examples and are not intended to limit the scope of the disclosure. These novel embodiments described above may be implemented in various other forms, and various omissions, substitutions, combinations, and changes may be made without departing from the spirit of the disclosure. These embodiments and modifications thereof are included in the scope and gist of the disclosure, and are also included in the disclosure described in the claims.

What is claimed is:

1. A substrate processing apparatus comprising:
a rotation holding unit including a rotary table and configured to rotate a substrate held by a holding member including a base;
a processing liquid supply unit including a nozzle configured to supply a processing liquid to an upper surface of the substrate while being rotated; and
a heating unit including a light source configured to irradiate light onto the upper surface of the substrate from above thereby heating the substrate,
wherein at least a portion of the holding member in contact with the substrate transmits the light irradiated from the heating unit.

2. The substrate processing apparatus according to claim 1, wherein an entire holding member is configured to transmit light.

3. The substrate processing apparatus according to claim 1, wherein the portion of the holding member that transmits the light is made of polytetrafluoroethylene (PCTFE).

4. The substrate processing apparatus according to claim 1, wherein the heating unit includes a transmissive window having a size equal to or larger than the substrate, and irradiates the light onto the substrate through the transmissive window.

5. The substrate processing apparatus according to claim 1, wherein the heating unit includes a plurality of light emitting diodes (LEDs) as the light source.

6. The substrate processing apparatus according to claim 1, wherein the holding member further includes a guide and a pin.

7. The substrate processing apparatus according to claim 6, wherein the base is a cylindrical member disposed on the rotary table and pivotable about an axis parallel to the rotary table.

8. The substrate processing apparatus according to claim 6, wherein the guide is a plate body standing on a top surface of the base and has an inclined surface that becomes higher toward an outer periphery of the rotary table.

9. The substrate processing apparatus according to claim 6, wherein the pin is a cylinder provided at a top of the guide at a position eccentric from an axis of the base.
